(19) United States
(12) Patent Application Publication
(10) Pub. No.: US 2025/0089291 A1
(43) Pub. Date: Mar. 13, 2025

(54) SEMICONDUCTOR DEVICE

(71) Applicant: FUJI ELECTRIC CO., LTD., Kawasaki-shi (JP)

(72) Inventor: Yasuyuki HOSHI, Matsumoto-city (JP)

(73) Assignee: FUJI ELECTRIC CO., LTD., Kawasaki-shi (JP)

(21) Appl. No.: 18/787,698

(22) Filed: Jul. 29, 2024

(30) Foreign Application Priority Data
Sep. 12, 2023 (JP) 2023-147989

(51) Int. Cl. H01L 29/78; H01L 29/06; H01L 29/861

(52) U.S. Cl. CPC H10D 30/665; H10D 8/411; H10D 30/668; H10D 62/106

(57) ABSTRACT

In a semiconductor substrate, on an n⁺-type starting substrate constituting an n⁺-type drain region, an n⁻-type epitaxial layer constituting an n⁻-type drift region, another n-type epitaxial layer constituting an n-type current spreading region, and a p-type epitaxial layer constituting a p-type base region are sequentially stacked. In the epitaxial layers, a crystallinity in an active-region operating portion, in which a trench gate structure is formed, is superior to a crystallinity in a region outside the active-region operating portion by removing a portion of the epitaxial layers having the superior crystallinity. Thus, in the stacked structure, in an entire region outside the active-region operating portion, all portions where the minority carrier lifetime is longer than the minority carrier lifetime of the n⁻-type drift region are completely removed, thereby making the minority carrier lifetime uniform.

### CROSS REFERENCE TO RELATED APPLICATIONS

This application is based upon and claims the benefit of priority of the prior Japanese Patent Application No. 2023-147989, filed on Sep. 12, 2023, the entire contents of which are incorporated herein by reference.

### BACKGROUND OF THE INVENTION

### 1. Field of the Invention

Embodiments of the invention relate to a semiconductor device.

### 2. Description of the Related Art

A metal-oxide-semiconductor field effect transistor (MOSFET) in which parts of a MOS gate (an insulated gate with a three-layer metal-oxide-semiconductor (MOS) structure) are formed in an n-type epitaxial layer and a p-type epitaxial layer stacked on an n⁻-type epitaxial layer constituting an n⁻-type drift region is a commonly known conventional semiconductor device (for example, refer to Japanese Laid-Open Patent Publication No. 2020-120072, Japanese Patent No. 4640439, and Japanese Patent No. 6848382).

### SUMMARY OF THE INVENTION

According to an embodiment of the present invention, a semiconductor device includes: a semiconductor substrate having a first main surface and a second main surface opposite to each other; an active region provided in the semiconductor substrate; a termination region surrounding a periphery of the active region; a boundary region between the active region and the termination region; a first semiconductor region of a first conductivity type, provided in the semiconductor substrate, spanning the active region to the termination region; a second semiconductor region of a second conductivity type, provided between the first semiconductor region and the first main surface of the semiconductor substrate; a device structure provided in the active region, the device structure having a pn junction between the second semiconductor region and the first semiconductor region; a second-conductivity-type outer peripheral region provided in the boundary region, between the first main surface and the first semiconductor region; a first electrode provided at the first main surface, and electrically connected to the device structure and the second-conductivity-type outer peripheral region; and a second electrode provided at the second main surface of the semiconductor substrate. The semiconductor substrate has a stacked structure including: a first epitaxial layer of the first conductivity type having the second-conductivity-type outer peripheral region therein at a first main surface side thereof, and a remaining portion of the first epitaxial layer, excluding the second-conductivity-type outer peripheral region, constitutes the first semiconductor region, and a second epitaxial layer provided on the first epitaxial layer. The second epitaxial layer is provided only in the active region and has the device structure. The first main surface in the active region is formed by the second epitaxial layer, and the first main surface outside the active region is formed by the first epitaxial layer.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a semiconductor device according to an embodiment is viewed from a front side of a semiconductor substrate thereof.

FIG. 2 is a cross-sectional view depicting a structure along cutting line A-A′ in FIG. 1.

FIG. 3 is a cross-sectional view depicting another example of the structure along cutting line A-A′ in FIG. 1.

FIG. 4 is a cross-sectional view depicting the structure along cutting line B-B′ in FIG. 1.

FIG. 5 is a cross-sectional view depicting the structure along cutting line C-C′ in FIG. 1.

FIG. 6 is a plan view depicting a layout when a semiconductor device of a reference example is viewed from a front side of a semiconductor substrate thereof.

FIG. 7 is a cross-sectional view depicting the structure along cutting line AA-AA′ in FIG. 6.

FIG. 8 is a cross-sectional view depicting the structure along cutting line BB-BB′ in FIG. 6.

FIG. 9 is a cross-sectional view depicting the structure along cutting line CC-CC′ in FIG. 6.

### DETAILED DESCRIPTION OF THE INVENTION

First, problems associated with the conventional techniques are described. The n-type epitaxial layer and the p-type epitaxial layer in which the parts of the MOS gate structure are formed has a long carrier lifetime due to good crystallinity as compared to the n⁻-type drift region. A portion with a long carrier lifetime as compared to the n⁻-type drift region is destroyed locally during switching of the MOSFET and as a result, overall breakdown tolerance of the MOSFET decreases.

Embodiments of a semiconductor device according to the present invention are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

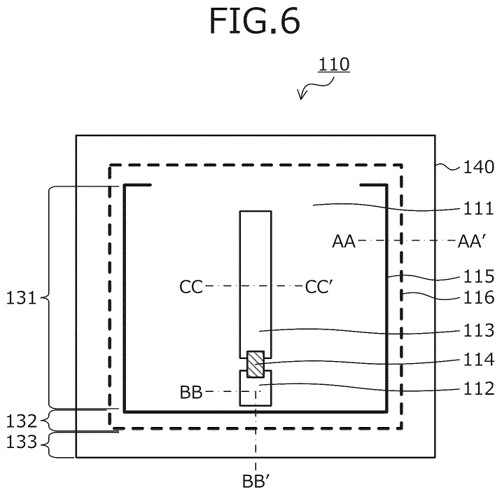

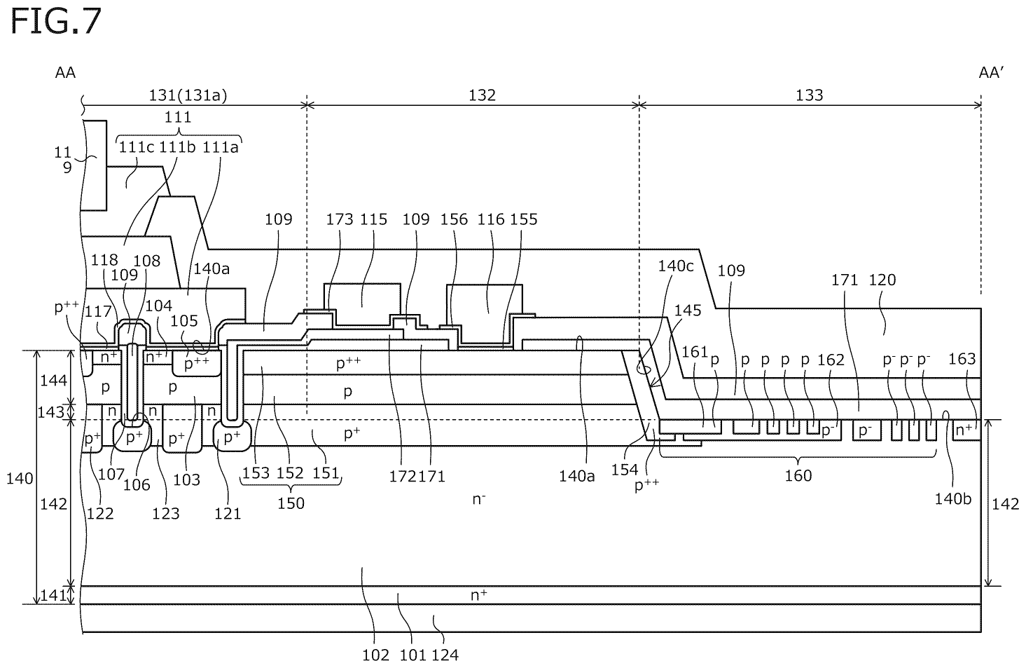

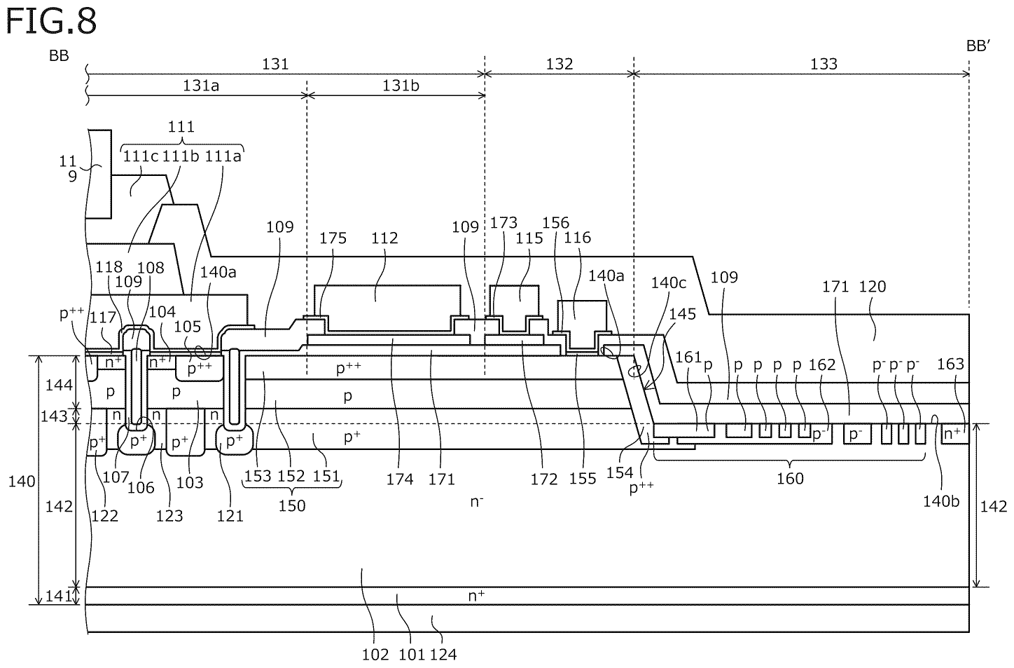

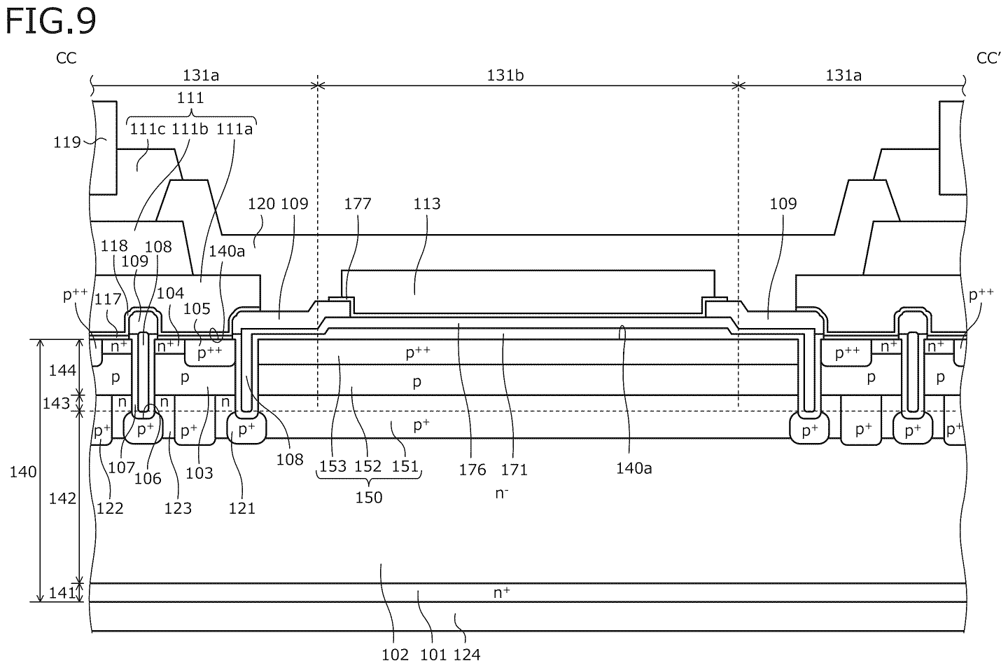

Problems associated with a semiconductor device of a reference example are discussed. FIG. 6 is a plan view depicting a layout when the semiconductor device of the reference example is viewed from a front side of a semiconductor substrate thereof. FIGS. 7, 8, and 9 are cross-sectional views depicting, respectively, a structure along cutting line AA-AA′, cutting line BB-BB′, and cutting line CC-CC′ in FIG. 6. A semiconductor device 110 of the reference example depicted in FIGS. 6 to 9 is a vertical MOSFET with a trench gate structure having a metal wiring layer in a boundary region 132 between an active region 131 and an edge termination region 133 of a semiconductor substrate (semiconductor chip) 140 that contains silicon carbide (SiC) as a semiconductor material, the vertical MOSFET further having a predetermined voltage withstanding structure 160 in the edge termination region 133.

An electrode pad such as a source pad (a source electrode 111) and a gate pad 112, a gate runner 113, a metal wiring layer such as a gate ring 115 and a source ring 116, and gate polysilicon wiring layers 172, 174, 176 and a gate resistor 114 containing a polysilicon (poly-Si) are provided on a front surface of the semiconductor substrate 140. The source electrode 111 is provided in an operating region (hereinafter, active-region operating portion) 131a of the active region 131 and covers substantially an entire surface of the active-region operating portion 131a.

The gate pad 112 and the gate runner 113, and the gate polysilicon wiring layers 174, 176 and the gate resistor 114 directly beneath (at lower surfaces of the gate pad 112 and the gate runner 113 facing an n⁺-type drain region 101) are provided in a non-operating region (hereinafter, active-region non-operating portion) 131b of the active region 131. The gate ring 115, the source ring 116, and the gate polysilicon wiring layer 172 directly beneath the gate ring 115 are provided in the boundary region 132. Gate electrodes 108 of all the cells of the MOSFET are connected to the gate polysilicon wiring layers 172, 176.

The gate pad 112, the gate runner 113, and the gate ring 115 are electrically connected to the gate polysilicon wiring layers 174, 176, 172 via barrier metals 175, 177, 173, respectively. The gate polysilicon wiring layer 174 directly beneath the gate pad 112 is connected to one end of the gate resistor 114. The gate polysilicon wiring layer 176 directly beneath the gate runner 113 is connected to the other end of the gate resistor 114 and is electrically connected to the gate pad 112 via the gate resistor 114. The gate resistor 114 is formed by, for example, ion implantation of an n-type dopant in the polysilicon.

The gate ring 115 has an open portion of a substantially rectangular shape and surrounds a periphery of the active region 131. The gate polysilicon wiring layer 172 directly beneath the gate ring 115 has an open portion of a substantially rectangular shape like the gate ring 115 and surrounds the periphery of the active region 131 or surrounds the periphery of the active region 131 in a closed, substantially rectangular shape. The source ring 116 is disposed farther outward (closer to a chip end) than is the gate ring 115 and surrounds the periphery of the active region 131 in a substantially rectangular shape. The source ring 116 is connected to the source electrode 111 at the open portion of the gate ring 115 and is fixed to a potential of the source electrode 111.

The active region 131 has a substantially rectangular shape in a plan view of the device and is provided in substantially a center (chip center) of the semiconductor substrate 140. The active region 131 is a portion on an inner side (chip center side) from an inner peripheral end (end facing the chip center) of the gate polysilicon wiring layer 172 directly beneath the gate ring 115. The active-region operating portion 131a is a region functioning as the MOSFET, with cells (functional units of a device) of the MOSFET disposed therein. The active-region non-operating portion 131b is a region excluding the active-region operating portion 131a and not functioning as the MOSFET.

The boundary region 132 is a portion from the inner peripheral end of the gate polysilicon wiring layer 172 to a later-described step 145 (boundary between a first portion 140a and a third portion 140c of the front surface of the semiconductor substrate 140); the boundary region 132 is adjacent to the active region 131 and surrounds the periphery of the active region 131. The edge termination region 133 is a region between the boundary region 132 and an end (chip end) of the semiconductor substrate 140; the edge termination region 133 is adjacent to the boundary region 132 and surrounds a periphery of the boundary region 132. Device elements of the active region 131 and the boundary region 132 are separated from device elements of the edge termination region 133 by a later-described third portion 140c of the front surface of the semiconductor substrate 140.

In the semiconductor substrate 140, an n⁻-type epitaxial layer 142 constituting an n⁻-type drift region 102, an n-type epitaxial layer 143 constituting an n-type current spreading region 123, and a p-type epitaxial layer 144 constituting a p-type base region 103 are stacked sequentially, in the order stated, on a front surface of an n⁺-type starting substrate 141 containing SiC as a semiconductor material. The n⁺-type starting substrate 141 constitutes the n⁺-type drain region 101. The semiconductor substrate 140 has, as the front surface, a main surface having the p-type epitaxial layer 144 and has, as a back surface, a main surface having the n⁺-type starting substrate 141.

The step 145 is formed at the front surface of the semiconductor substrate 140 by removing portions of the epitaxial layers 144, 143 in the edge termination region 133. The epitaxial layers 143, 144 are left in a mesa-like shape in the active region 131 and the boundary region 132. A portion (hereinafter, first portion) 140a of the front surface of the semiconductor substrate 140 in the active region 131 and the boundary region 132 is an exposed surface of the p-type epitaxial layer 144 while a portion (hereinafter, second portion) 140b of the front surface of the semiconductor substrate 140 in the edge termination region 133 is an exposed surface of the n⁻-type epitaxial layer 142.

In the epitaxial layers 143, 144, a device structure (trench gate structure) of the semiconductor device 110 and a p-type outer peripheral region 150 are provided. The trench gate structure is configured by the p-type base region 103, n⁺-type source regions 104, p⁺⁺-type contact regions 105, trenches 106, gate insulating films 107, and the gate electrodes 108 provided in the active-region operating portion 131a. P⁺-type regions 121, 122 for mitigating electric field and the n-type current spreading region 123 are each selectively provided near bottoms of the trenches 106.

The p-type outer peripheral region 150 is provided between the front surface of the semiconductor substrate 140 (the first portion 140a) and the n⁻-type drift region 102, in an entire area of the active-region non-operating portion 131b and the boundary region 132. The p-type outer peripheral region 150 is configured by p-type regions 151, 152, 153 adjacent to one another in a depth direction, each having a different doping concentration. The p-type outer peripheral region 150 is fixed to the potential of the source electrode 111 via the source ring 116. In the boundary region 132, the p-type outer peripheral region 150 surrounds the periphery of the active region 131 and extends in the active-region non-operating portion 131b.

In the active-region non-operating portion 131b, all the p-type regions 151 to 153 configuring the p-type outer peripheral region 150 face the gate pad 112, the gate runner 113, the gate resistor 114, and the gate polysilicon wiring layer 174, with a field oxide film 171 intervening therebetween. In the boundary region 132, all the p-type regions 151 to 153 configuring the p-type outer peripheral region 150 face the gate ring 115, the source ring 116, and the gate polysilicon wiring layers 172, 176, with the field oxide film 171 intervening therebetween.

The third portion 140c connecting the first portion 140a and the second portion 140b of the front surface of the semiconductor substrate 140 is side surfaces of the epitaxial layers 143, 144 exposed by the formation of the step 145. A p⁺⁺-type connecting region 154 along the third portion 140c of the front surface of the semiconductor substrate 140 connects outer peripheral ends (ends closer to the chip end) of the p-type regions 151 to 153. The p⁺⁺-type connecting region 154 is along an entire area of the third portion 140c of the front surface of the semiconductor substrate 140 and has a function of mitigating electric field near the third portion 140c.

The p-type base region 103, the n⁺-type source regions 104, the p⁺⁺-type contact regions 105, the p⁺-type regions 122, the n-type current spreading region 123, the p-type regions 151 to 153, and the p⁺⁺-type connecting region 154 provided in the active region 131 and the boundary region 132 are configured by the epitaxial layers 143, 144, are diffused regions formed by ion implantation in surface regions of the epitaxial layers 143, 144, or are regions including portions that are diffused regions formed by ion implantation in the epitaxial layers 143, 144.

In the edge termination region 133, p-type regions 161, 162 configuring the voltage withstanding structure 160 and an n⁺-type channel stopper region 163 are disposed in the semiconductor substrate 140, at the front surface of the semiconductor substrate 140. Thus, as described above, the epitaxial layers 143, 144 are removed in the edge termination region 133, whereby the n⁻-type epitaxial layer 142 is exposed at the front surface of the semiconductor substrate 140 (second portion 140b). The p-type regions 161, 162 and the n⁺-type channel stopper region 163 are diffused regions formed by ion implantation in surface regions of the n⁻-type epitaxial layer 142.

In the boundary region 132 and the edge termination region 133, the front surface of the semiconductor substrate 140 is covered by an insulating layer constituted by the field oxide film 171 and an interlayer insulating film 109. An external connection terminal 119 is soldered to a portion (source pad) of the source electrode 111 (111a, 111b, 111c) exposed in a contact hole of a passivation film 120. In an entire area of the back surface (back surface of the n⁺-type starting substrate 141) of the semiconductor substrate 140, a drain electrode 124 is provided in contact with the n⁺-type starting substrate 141 (the n⁺-type drain region 101).

However, in the semiconductor device 110 of the reference example (MOSFET), crystallinity of the n-type epitaxial layer 143 and the p-type epitaxial layer 144 is good as compared to the n⁻-type epitaxial layer 142 (the n⁻-type drift region 102) and thus, the lifetime of minority carriers (holes in n-type regions and electrons of p-type regions formed in the epitaxial layers 143, 144) becomes long. One reason for this is that the rate of crystal growth (epitaxial growth) differs for the n⁻-type epitaxial layer 142 and the epitaxial layers 143, 144 due to the roles of each being different.

The n⁻-type epitaxial layer 142 is relatively thick to sustain a predetermined breakdown voltage and thus, is grown in a relatively short time with some sacrifice to crystallinity. On the other hand, the epitaxial layers 143, 144 are portions where the trench gate structure is formed and since crystallinity affects device characteristics of the MOSFET, time is taken to grow the epitaxial layers 143, 144 to have good crystallinity. In particular, the p-type epitaxial layer 144 is in contact with the gate insulating films 107 and channels (n-type inversion layer) are formed therein when the MOSFET is on and therefore, favorable crystallinity is necessary.

The lifetime of minority carriers being different in the n⁻-type epitaxial layer 142 and in the epitaxial layers 143, 144 results in the following problems. During the period while the MOSFET transitions from on to off, parasitic pn junction diodes (body diodes) formed by pn junctions between the p-type base region 103, the p⁺-type regions 121, 122, the p-type outer peripheral region 150, the n-type current spreading region 123, and the n⁻-type drift region 102 conduct in the forward direction, minority carriers (holes and electrons) are injected into and accumulate in the n⁻-type drift region 102.

Due to this state, when the MOSFET turns off (transition period from conduction of the body diodes in the forward direction, to an off state of the MOSFET), holes in the n⁻-type drift region 102 are discharged to the source electrode 111, whereby holes from the n⁻-type drift region 102 decrease. At this time, holes in the n⁻-type drift region 102 are discharged to the source electrode 111 or the source ring 116. In the active-region operating portion 131a, the area of source contact is relatively large, whereby holes in the n⁻-type drift region 102 are discharged relatively uniformly to the source electrode 111.

On the other hand, holes in the n⁻-type drift region 102 in the active-region non-operating portion 131b, the boundary region 132, and the edge termination region 133 easily flow into the p-type outer peripheral region 150 (the epitaxial layers 143, 144 in the active-region non-operating portion 131b and the boundary region 132), pass through the p-type outer peripheral region 150, and are discharged to the source ring 116. The lifetime of the minority carriers of the p-type type outer peripheral region 150 is relatively long, whereby a period until the carriers in the p-type outer peripheral region 150 disappear becomes longer.

Thus, the period until the reverse recovery current (hole current) of the body diodes is blocked varies due to a path along which the holes in the n⁻-type drift region 102 are discharged to the source electrode 111 or the source ring 116. When dV/dt (rate of change of drain-source voltage) is small, holes in the n⁻-type drift region 102 are uniformly discharged to the source ring 116 even by the path through the p-type outer peripheral region 150, however, when dV/dt is large and steep, locations and a range of the area of delayed extraction of the hole current increase, whereby hole current easily concentrates in such locations.

In the active-region non-operating portion 131b, the boundary region 132, and the edge termination region 133, locations where extraction of the hole current is delayed include four corner portions (vertices) of the gate pad 112, which has a substantially rectangular shape in a plan view of the device, four corner portions (vertices of the semiconductor substrate 140) of the edge termination region 133 surrounding the periphery of the boundary region 132 in a substantially rectangular shape, a vicinity of the gate resistor 114, and vicinities of other circuit structure portions (not depicted). In such locations (particularly, the boundary region 132), breakdown tolerance during switching of the MOSFET, particularly, tolerance against dV/dt decreases locally, leading to destruction.

In particular, this problem appears more prominently the lower is the temperature (junction temperature) of the semiconductor substrate 140 (junction temperature). One reason for this is that, the lower is the temperature of the semiconductor substrate 140, the higher is the sheet resistance of p-type regions in the semiconductor substrate 140, when SiC is used as a semiconductor material. The lower is the temperature of the semiconductor substrate 140, the higher is the resistance of the p-type outer peripheral region 150, and holes flowing into the p-type outer peripheral region 150 from the n⁻-type drift region 102 during reverse recovery of the body diodes of the MOSFET do not flow easily within the p-type outer peripheral region 150.

For example, in the semiconductor device 110 of the reference example, when the temperature of the semiconductor substrate 140 is a low temperature of about −40 degrees C. or −55 degrees C., reverse recovery current that is about two times to three times the rated current flows to the body diodes during a period until reverse recovery current of the body diodes is blocked, which may lead to destruction. In the present embodiment, problems to be solved include, for example, improving reverse recovery characteristics of the body diodes and enhancing breakdown tolerance, particularly tolerance against steep dV/dt of the MOSFET (semiconductor device).

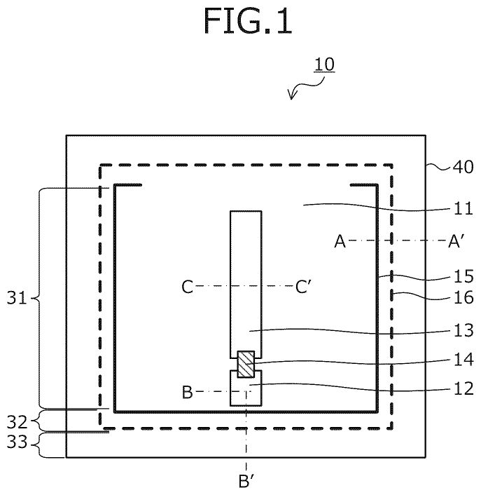

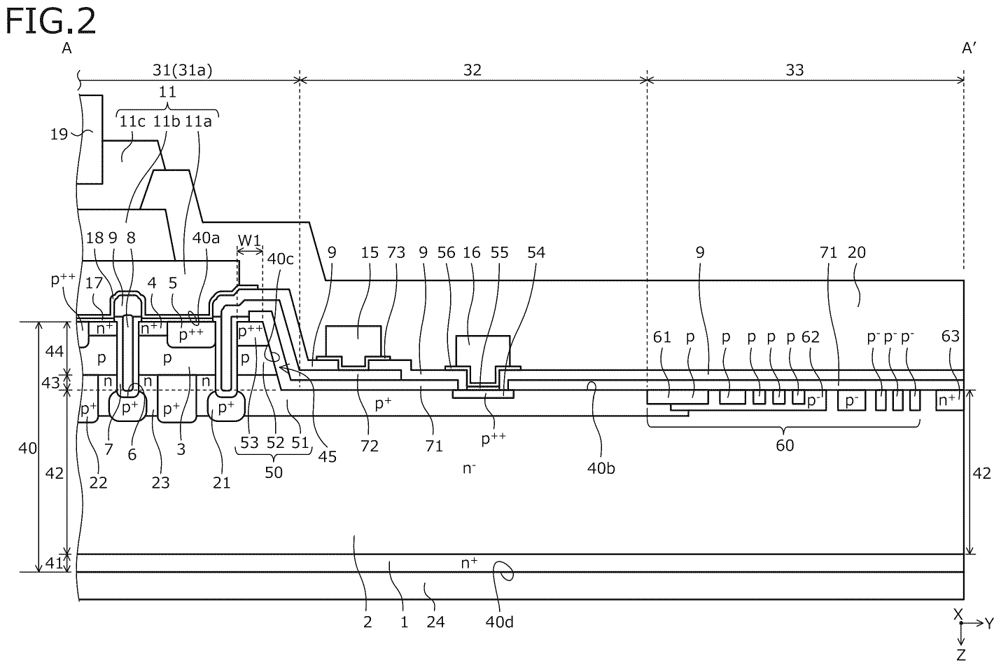

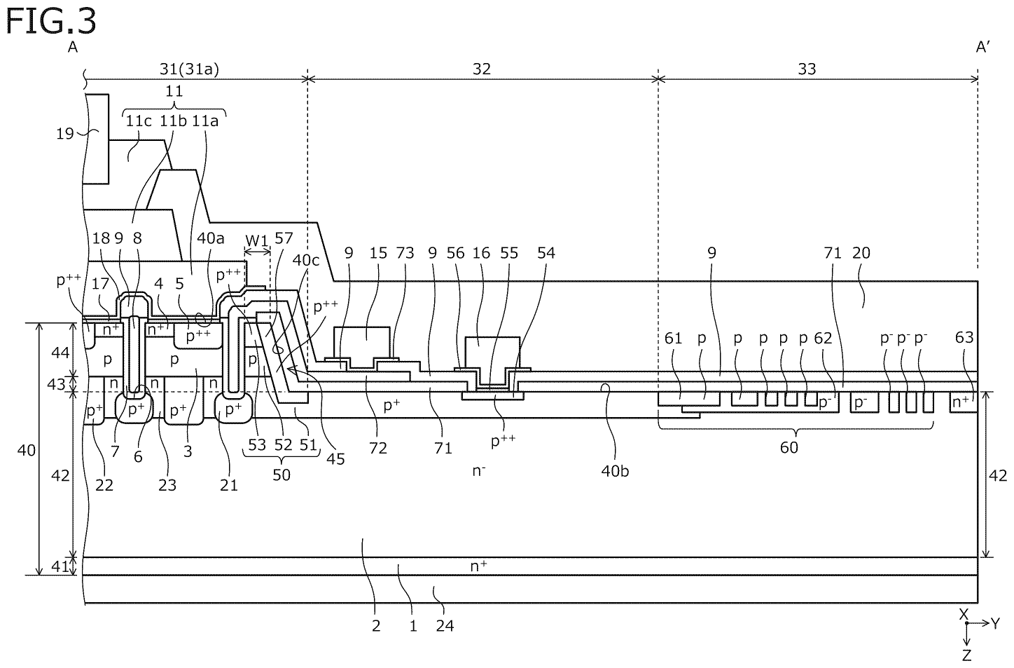

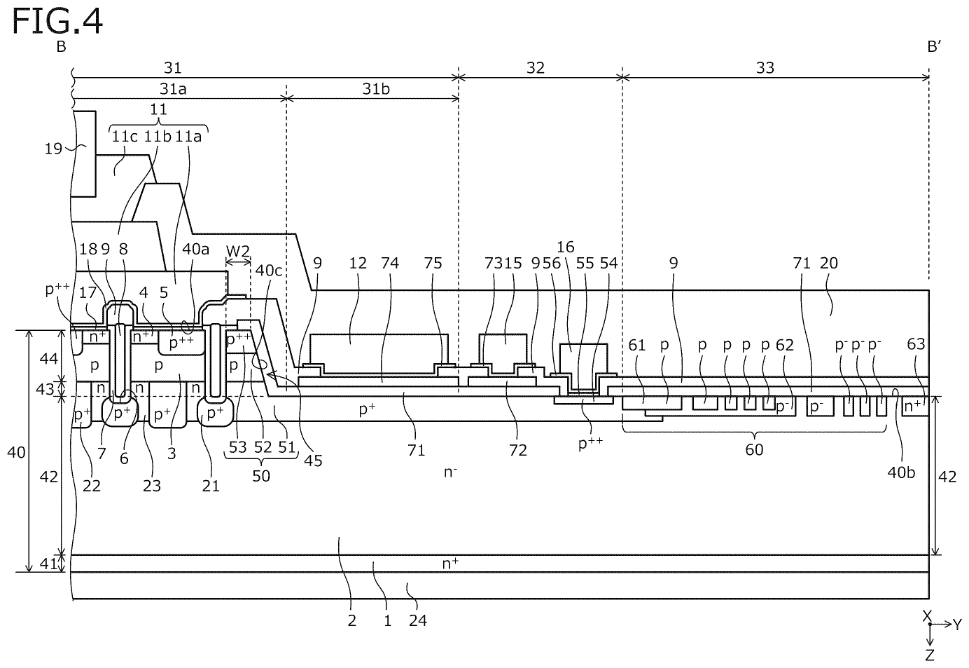

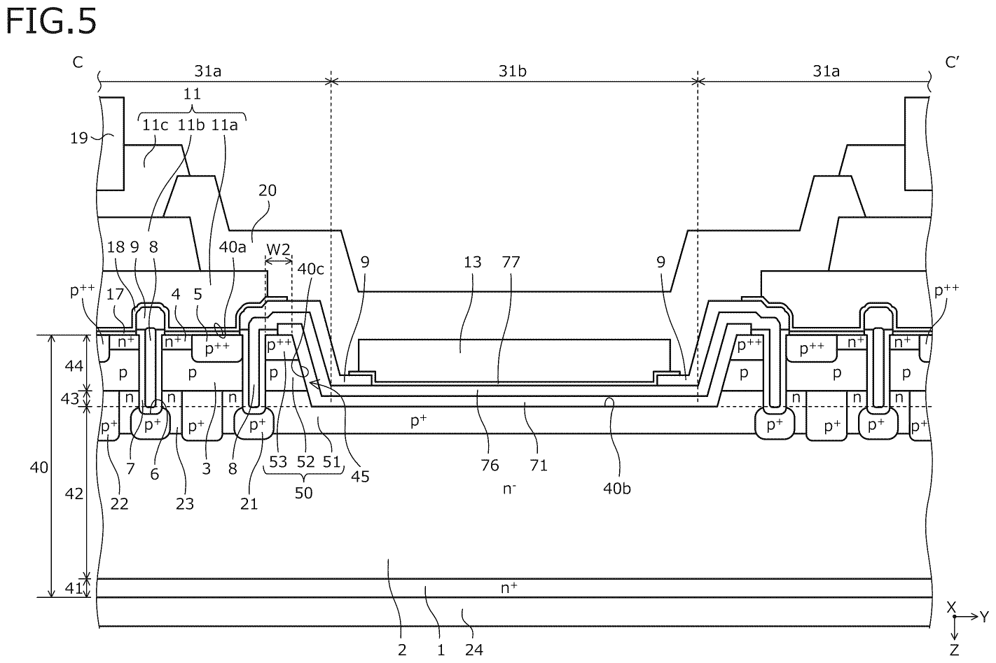

A structure of a semiconductor device according to an embodiment is described. FIG. 1 is a plan view depicting a layout when the semiconductor device according to the embodiment is viewed from a front side of a semiconductor substrate thereof. FIGS. 2, 4, and 5 are cross-sectional views depicting, respectively, the structure along cutting line A-A′, cutting line B-B′, and cutting line C-C′ in FIG. 1. FIG. 3 is a cross-sectional view depicting another example of the structure along cutting line A-A′ in FIG. 1. A semiconductor device 10 according to the embodiment depicted in FIGS. 1 to 5 has a metal wiring layer in a boundary region 32 between an active region 31 and an edge termination region 33 of a semiconductor substrate (semiconductor chip) 40 containing silicon carbide (SIC) as a semiconductor material, the semiconductor device 10 being a vertical MOSFET with a trench gate structure (insulated gate structure having a three-layer metal-oxide-semiconductor structure: device structure) having a predetermined voltage withstanding structure 60 in the edge termination region 33.

The active region 31 is a region through which a main current (drift current) flows when the MOSFET is on. The active region 31, for example, has a substantially rectangular shape in a plan view of the device and is disposed in substantially a center (chip center) of the semiconductor substrate 40. The active region 31 occupies a majority of the area (surface area) of the semiconductor substrate 40. An operating region (active-region operating portion) 31a of the active region 31 is a portion in which later-described epitaxial layers 43, 44 are disposed; the active-region operating portion 31a functions as the MOSFET. In the active-region operating portion 31a, multiple cells (functional units of a device) each having a same MOSFET structure are disposed adjacent to one another. A non-operating region (active-region non-operating portion) 31b of the active region 31 is a region of the active region 31, excluding the active-region operating portion 31a, the non-operating region 31b is free of the MOSFET cells and does not function as the MOSFET.

The boundary region 32 is a portion farther outward (closer to the chip end) than is a later-described step 45 and farther inward (closer to the chip center) than is the voltage withstanding structure 60; the boundary region 32 is adjacent to the active region 31 and surrounds a periphery of the active region 31 in a substantially rectangular shape in the plane view of the device. The edge termination region 33 is a region between the boundary region 32 and an end (chip end) of the semiconductor substrate 40; the edge termination region 33 is adjacent to the boundary region 32 and surrounds a periphery of the boundary region 32 in a substantially rectangular shape. Device elements of the active region 31 and the boundary region 32 are separated from device elements of the edge termination region 33 by pn junctions between a later-described p-type outer peripheral region 50 and an n⁻-type drift region 2. Widths (widths in a direction from the chip center to the chip end) of the active region 31, the boundary region 32, and the edge termination region 33 are the same, respectively, as the widths of the active region 131, the boundary region 132, and the edge termination region 133 in the reference structure (refer to FIGS. 6 to 9).

On a front surface of the semiconductor substrate 40, electrode pads such as a source pad (a source electrode 11) and a gate pad 12, a metal wiring layer such as a gate runner 13, a gate ring 15 (thick line in FIG. 1) and a source ring 16 (dashed line in FIG. 1), a gate resistor 14 containing a polysilicon (hatched portion in FIG. 1), and gate polysilicon wiring layers 72, 74, 76 (not depicted in FIG. 1) are provided. The source electrode (first electrode) 11 is provided in the active-region operating portion 31a and covers substantially an entire surface of the active-region operating portion 31a. The source electrode 11 may be disposed separately in two or more locations in the active-region operating portion 31a. For example, configuration may be such that, in the active region 31, the gate runner 13 extends linearly in a direction parallel to the front surface of the semiconductor substrate 40 and passes through substantially the center of the semiconductor substrate 40, two of the source electrodes 11 are disposed with line symmetry with respect to the gate runner 13, and multiple cells with the same structure are disposed with line symmetry with respect to the gate runner 13.

The gate pad 12, the gate runner (gate wiring layer) 13, the gate polysilicon wiring layers (gate wiring layer) 74, 76 directly beneath (side facing an n⁺-type drain region 1) the gate pad 12 and the gate runner 13, and the gate resistor 14 are provided in the active-region non-operating portion 31b. The gate ring (gate wiring layer) 15, the source ring 16, and the gate polysilicon wiring layer (gate wiring layer) 72 directly beneath the gate ring 15 are provided in the boundary region 32. The gate pad 12, for example, has a substantially rectangular shape in a plan view of the device and is disposed near a boundary between the active region 31 and the boundary region 32. The gate runner 13 has a first end that faces the gate pad 12, the gate runner 13 extending linearly away from the gate pad 12 in a later-described first direction X so as to pass through substantially the center of the semiconductor substrate 40.

The gate resistor 14 is disposed between the gate pad 12 and the gate runner 13. The gate ring 15 is disposed apart from the gate pad 12 and the gate runner 13, for example, the gate ring 15 has an open portion of a substantially rectangular shape near a second end of the gate runner 13 and surrounds the periphery of the active region 31. The gate polysilicon wiring layer 72 directly beneath the gate ring 15 has an open portion of a substantially rectangular shape like the gate ring 15 and surrounds the periphery of the active region 31 or surrounds the periphery of the active region 31 in a closed, substantially rectangular shape. The source ring 16 is disposed closer to the chip end than is the gate ring 15 and surrounds the periphery of the active region 31 in a substantially rectangular shape in a plane view. The source ring 16 is connected to the source electrode 11 at the open portion of the gate ring 15 and is fixed to a potential of the source electrode 11.

In the semiconductor substrate 40, on a front surface of an n⁺-type starting substrate 41 containing SiC as a semiconductor material, the n⁻-type epitaxial layer 42 (first epitaxial layer) 42 constituting the n⁻-type drift region (first semiconductor region) 2, the n-type epitaxial layer (second epitaxial layer) 43 constituting an n-type current spreading region 23, and the p-type epitaxial layer (second epitaxial layer) 44 constituting a p-type base region (second semiconductor region) 3 are sequentially stacked in the order stated. The n⁺-type starting substrate 41 constitutes the n⁺-type drain region 1. The n⁻-type epitaxial layer 42 is relatively thick to sustain a predetermined breakdown voltage and thus, may be grown in a relatively short time with some sacrifice to crystallinity. Crystallinity of the epitaxial layers 43, 44 affects device characteristics of the MOSFET (the semiconductor device 10) and therefore, time is taken to grow the epitaxial layers 43, 44 to have good crystallinity.

The semiconductor substrate 40 has, as the front surface, a first main surface formed by either a surface (40b) of the p-type epitaxial layer 44 or a surface (40a) of the n⁻-type epitaxial layer 42, and has, as a back surface, a second main surface 40d. The step 45 is formed at the front surface of the semiconductor substrate 40 by etching and completely removing portions of the epitaxial layers 44, 43 in the active-region non-operating portion 31b, the boundary region 32, and the edge termination region 33. The front surface of the semiconductor substrate 40, with the step 45 being a boundary, has a portion (hereinafter, first portion) 40a in the active-region operating portion 31a and a portion in (hereinafter, second portion) 40b in the active-region non-operating portion 31b, the boundary region 32, and the edge termination region 33, the second portion 40b being recessed toward the n⁺-type drain region 1 as compared to the first portion 40a. The epitaxial layers 43, 44 are left only in the active-region operating portion 31a.

As described, the semiconductor substrate 40, in an entire area excluding the active-region operating portion 31a, has a stacked structure in which only the n⁻-type epitaxial layer 42, which constitutes the n⁻-type drift region 2 is stacked on the n⁺-type starting substrate 41. Thus, even when the crystallinity of the n⁻-type epitaxial layer 42 is inferior to the crystallinity of the epitaxial layers 43, 44, the semiconductor substrate 40 may have a stacked structure in which in the entire area excluding the active-region operating portion 31a, portions where the crystallinity is relatively good are completely removed. In other words, the semiconductor substrate 40 has a stacked structure in which, in the active-region non-operating portion 31b, the boundary region 32, and the edge termination region 33, portions where the lifetime of the minority carriers is longer than the lifetime of the minority carriers in the n⁻-type drift region 2 are completely removed and the lifetime of the minority carriers is made substantially uniform.

The first portion 40a of the front surface of the semiconductor substrate 40 is an exposed surface of the p-type epitaxial layer 44 and the second portion 40b is an exposed surface of the n⁻-type epitaxial layer 42. Near a boundary between the active-region operating portion 31a and the active-region non-operating portion 31b, and near a boundary between the active-region operating portion 31a and the boundary region 32, preferably, respective distances W1, W2 from the step 45 (the boundary between the first portion 40a and the later-described third portion 40c) to a sidewall of a nearest one of multiple trenches 6 (the nearest one being nearest to the step 45) may about 5 μm or less. The entire step 45 (i.e., from the boundary between the first portion 40a and the third portion 40c to a boundary between the second portion 40b and the third portion 40c) is located in the active-region operating portion 31a. During formation of the step 45, a surface region of the n⁻-type epitaxial layer 42 may be slightly removed with the epitaxial layers 44, 43.

The third portion 40c, which connects the first portion 40a and the second portion 40b of the front surface of the semiconductor substrate 40, is side surfaces of the epitaxial layers 43, 44 exposed by the formation of the step 45. The third portion 40c of the front surface of the semiconductor substrate 40 may be orthogonal to the first and second portions 40a, 40b of the front surface of the semiconductor substrate 40 or may be inclined so that the epitaxial layers 43, 44 form a trapezoidal shape in a cross-sectional view of the device. In the epitaxial layers 43, 44, only the trench gate structure is provided. Crystallinity affects device characteristics of the MOSFET and thus, preferably, the epitaxial layers 43, 44 have good crystal growth. The trench gate structure is configured by the p-type base region 3, n⁺-type source regions 4, p⁺⁺-type contact regions 5, the trenches 6, gate insulating films 7, and gate electrodes 8.

The p-type base region 3 is provided in an entire area of the active-region operating portion 31a, between the first portion 40a of the front surface of the semiconductor substrate 40 and the n⁻-type epitaxial layer 42 (the n⁻-type drift region 2). The p-type base region 3 reaches the third portion 40c of the front surface of the semiconductor substrate 40. The p-type base region 3 is adjacent to all sidewalls of all the trenches 6. The n⁺-type source regions 4 and the p⁺⁺-type contact regions 5 are diffused regions formed by ion implantation in surface regions of the p-type epitaxial layer 44. The n⁺-type source regions 4 and the p⁺⁺-type contact regions 5 are each selectively provided between the first portion 40a of the front surface of the semiconductor substrate 40 and the p-type base region 3 and are in contact with the p-type base region 3. The n⁺-type source regions 4 and the p⁺⁺-type contact regions 5 are in contact with ohmic electrodes 17 at the first portion 40a of the front surface of the semiconductor substrate 40.

The n⁺-type source regions 4 are provided adjacent to the sidewalls of the trenches 6 and are in contact with the gate insulating films 7 at the sidewalls of the trenches 6. A first outermost one of the trenches 6 (the first outermost one being nearest the active-region non-operating portion 31b in a later-described second direction Y (lateral direction of the trenches 6) has a first sidewall farther from a boundary between the active-region operating portion 31a and the active-region non-operating portion 31b and a second sidewall closer to the boundary between the active-region operating portion 31a and the active-region non-operating portion 31b; a second outermost one of the trenches 6 (the second outermost one being nearest the boundary region 32 in the second direction Y) has a first sidewall farther from a boundary between the active-region operating portion 31a and the boundary region 32 and a second sidewall closer to the boundary between the active-region operating portion 31a and the boundary region 32; one of the p⁺⁺-type contact regions 5 is provided adjacent to the first sidewall of the first outermost one of the trenches 6; one of the p⁺⁺-type contact regions 5 is provided adjacent to the first sidewall of the second outermost one of the trenches 6; and the later-described p-type outer peripheral region 50 is provided adjacent to the second sidewall of the first outermost one of the trenches 6 and the second sidewall of the second outermost one of the trenches 6, the second sidewalls being free of the n⁺-type source regions 4. The p-type outer peripheral region 50 surrounds a periphery of the active-region operating portion 31a and is adjacent to end-sidewalls (sidewalls in a longitudinal direction (the later-described first direction X)) of the trenches 6. The p-type base region 3, the n⁺-type source regions 4, and the p⁺⁺-type contact regions 5 extend linearly in the first direction X and respective ends thereof in the first direction X are in contact with the p-type outer peripheral region 50.

A portion of the p-type epitaxial layer 44, excluding the n⁺-type source regions 4, the p⁺⁺-type contact regions 5, and the later-described p-type outer peripheral region 50, constitutes the p-type base region 3. The p⁺⁺-type contact regions 5 may be omitted. In this instance, instead of the p⁺⁺-type contact regions 5, the p-type base region 3 is at the front surface of the semiconductor substrate 40. The trenches 6 penetrate through the p-type epitaxial layer 44 from the first portion 40a of the front surface of the semiconductor substrate 40 in a depth direction Z and terminate in the n-type epitaxial layer 43. The trenches 6, for example, extend linearly in the first direction X (longitudinal direction), which is parallel to the front surface of the semiconductor substrate 40; the trenches 6 are disposed adjacent to one another in the second direction Y (lateral direction), in a striped pattern, the second direction being parallel to the front surface of the semiconductor substrate 40 and orthogonal to the first direction X. In the trenches 6, the gate electrodes 8 are provided via the gate insulating films 7.

Between the p-type base region 3 and the n⁻-type drift region 2, p⁺-type regions 21, 22 and the n-type current spreading region 23 are each selectively provided reaching positions closer to the n⁺-type drain region 1 than are bottoms of the trenches 6b. The p⁺-type regions 21 are diffused regions formed by ion implantation in surface regions of the n⁻-type epitaxial layer 42. The p⁺-type regions 22 and the n-type current spreading region 23 are diffused regions formed by ion implantation, from the n-type epitaxial layer 43 to surface regions of the n⁻-type epitaxial layer 42. The p⁺-type regions 21, 22 are fixed to the potential of the source electrode 11, deplete (or cause the n-type current spreading region 23 to deplete, or both) when the MOSFET is off, and have a function of mitigating electric field near the bottoms of the trenches 6. The p⁺-type regions 21, 22 extend linearly in the first direction X and ends thereof in the first direction X are in contact with a later-described p⁺-type outer peripheral region 51.

The p⁺-type regions 21 are provided apart from the p-type base region 3 and face the bottoms of the trenches 6 in the depth direction Z. The p⁺-type regions 21 may be in contact with the gate insulating films 7 at the bottoms of the trenches 6 or may be apart from the trenches 6. Between any adjacent two of the trenches 6, one of the p⁺-type regions 22 is provided being apart from the trenches 6 and the p⁺-type regions 21 and having an upper surface (surface thereof facing the n⁺-type source regions 4) in contact with the p-type base region 3. Each of the p⁺-type regions 22 is formed by a lower portion (portion facing the n⁺-type drain region 1) formed in the n⁻-type epitaxial layer 42 and an upper portion (portion facing the n⁺-type source regions 4) formed in the n-type epitaxial layer 43 and continuous with the lower portion in the depth direction Z. The p⁺-type regions 21 may be formed concurrently with the lower portions of the p⁺-type regions 22. The p⁺-type regions 21, 22, at respective lower surfaces thereof (surfaces facing the n⁺-type drain region 1), may be in contact with the n⁻-type drift region 2.

The n-type current spreading region 23 is a so-called current spreading layer (CSL) that reduces carrier spreading resistance. The n-type current spreading region 23 is disposed adjacent to the p⁺-type regions 21, 22 and the trenches 6, has an upper surface in contact with the p-type base region 3 and a lower surface in contact with the n⁻-type drift region 2. The n-type current spreading region 23 is formed by a lower portion formed in the n⁻-type epitaxial layer 42 and an upper portion formed in the n-type epitaxial layer 43 and continuous with the lower portion in the depth direction Z. The n-type current spreading region 23 may be omitted. In this instance, instead of the n-type current spreading region 23, the n⁻-type drift region 2 extends between the p⁺-type regions 21, 22 adjacent to one another and reaches the p-type base region 3; the n⁻-type drift region 2 further extends between the p-type base region 3 and the p⁺-type regions 21 in the second direction Y and reaches the trenches 6.

A portion of the n⁻-type epitaxial layer 42, excluding the p⁺-type regions 21, 22, the n-type current spreading region 23, the later-described p⁺-type outer peripheral region 51, later-described FLRs 61, 62, and a later-described n⁺-type channel stopper region 63, constitutes the n⁻-type drift region 2. The n⁻-type drift region 2 is provided spanning the active region 31, the boundary region 32, and the edge termination region 33, and is exposed at the chip end (side surface of the semiconductor substrate 40). In the active-region non-operating portion 31b and the boundary region 32, in an entire area between the second portion 40b of the front surface of the semiconductor substrate 40 and the n⁻-type drift region 2, the p⁺-type outer peripheral region (second-conductivity-type outer peripheral region) 51 is provided in contact with the n⁻-type drift region 2. The p⁺-type outer peripheral region 51 is a diffused region formed by ion implantation in a surface region of the n⁻-type epitaxial layer 42. The p⁺-type outer peripheral region 51 surrounds the periphery of the active-region operating portion 31a.

The p⁺-type outer peripheral region 51 extends closer to the active-region operating portion 31a than is the step 45 of the front surface of the semiconductor substrate 40 and reaches a sidewall of a nearest one of the trenches 6 to the step 45. Further, the p⁺-type outer peripheral region 51 extends along the third portion 40c of the front surface of the semiconductor substrate 40 in a direction to the first portion 40a; an upper surface of the p⁺-type outer peripheral region 51 is in contact with the p-type epitaxial layer 44 between the third portion 40c of the front surface of the semiconductor substrate 40 and the nearest one of the trenches 6 to the step 45. The p⁺-type outer peripheral region 51 may be in contact with a nearest one of the p⁺-type regions 21 to the step 45; the p⁺-type regions 21 face the bottoms of the trenches 6. A depth of a lower surface of the p⁺-type outer peripheral region 51 may be substantially a same as a depth of lower surfaces of the p⁺-type regions 21. The p⁺-type outer peripheral region 51 is covered by a field oxide film 71. The p⁺-type outer peripheral region 51 is electrically connected to the source ring 16 via a later-described p⁺⁺-type outer peripheral contact region 54.

Between the third portion 40c of the front surface of the semiconductor substrate 40 and the nearest one of the trenches 6 to the step 45, the p-type epitaxial layer 44 (the p-type base region 3) constitutes a p-type outer peripheral base region 52. The p-type outer peripheral base region 52 extends along an outer periphery of the active-region operating portion 31a. In an entire area between the p-type outer peripheral base region 52 and the first and third portions 40a, 40c of the front surface of the semiconductor substrate 40, a p⁺⁺-type outer peripheral region 53 is provided. The p⁺⁺-type outer peripheral region 53 is a diffused region formed by ion implantation in a surface region of the p-type epitaxial layer 44. A lower surface of the p⁺⁺-type outer peripheral region 53 is in contact with the p-type outer peripheral base region 52. The p⁺⁺-type outer peripheral region 53 is adjacent to the sidewall of the nearest one of the trenches 6 to the step 45. The p⁺⁺-type outer peripheral region 53 extends along the outer periphery of the active-region operating portion 31a. The p⁺⁺-type outer peripheral region 53 may be formed concurrently with the p⁺⁺-type contact regions 5.

An entire surface of the p-type outer peripheral base region 52, excluding a contact surface thereof in contact with the p⁺-type outer peripheral region 51 and the p⁺⁺-type outer peripheral region 53, is in contact with one of the gate insulating films 7 and the field oxide film 71. An entire surface of the p⁺⁺-type outer peripheral region 53, excluding contact surfaces thereof in contact with the p-type outer peripheral base region 52, is in contact with the one of the gate insulating films 7 and the field oxide film 71. The p⁺⁺-type outer peripheral region 53 may be omitted. In this instance, instead of the p⁺⁺-type outer peripheral region 53, the p-type outer peripheral base region 52 reaches the first portion 40a of the front surface of the semiconductor substrate 40. Between the second portion 40b of the front surface of the semiconductor substrate 40 and the p⁺-type outer peripheral region 51, the p⁺⁺-type outer peripheral contact region 54 is selectively provided in contact with the p⁺-type outer peripheral region 51. The p⁺⁺-type outer peripheral contact region 54 is in contact with an ohmic electrode 55 at the second portion 40b of the front surface of the semiconductor substrate 40.

The p⁺-type outer peripheral region 51, the p-type outer peripheral base region 52, and the p⁺⁺-type outer peripheral region 53 adjacent to one another in the depth direction Z constitute the p-type outer peripheral region 50. The p-type outer peripheral region 50 surrounds the periphery of the active-region operating portion 31a. The p-type outer peripheral region 50 has a function of drawing out holes accumulated in the n⁻-type drift region 2 in the edge termination region 33 due to switching of MOSFET (the semiconductor device 10) or the like, the holes are drawn out to the later-described source electrode 11 or the source ring 16 when the MOSFET turns off. The source ring 16 is electrically connected to the p⁺-type outer peripheral region 51 in the active-region non-operating portion 31b and the boundary region 32, whereby the p-type outer peripheral region 50 is fixed to the potential of the source electrode 11. The p-type outer peripheral base region 52 and the p⁺⁺-type outer peripheral region 53 are not electrically connected to the source electrode 11 or the source ring 16 directly.

Along the third portion 40c of the front surface of the semiconductor substrate 40, a p⁺⁺-type connecting region 57 may be provided (refer to FIG. 3). The p⁺⁺-type connecting region 57 connects respective outer peripheral ends (ends facing the active-region non-operating portion 31b, ends facing the boundary region 32) of the p⁺-type outer peripheral region 51, the p-type outer peripheral base region 52, and the p⁺⁺-type outer peripheral region 53 to each other. The p⁺⁺-type connecting region 57 is along an entire area of the third portion 40c of the front surface of the semiconductor substrate 40 and a region of the second portion 40b at the boundary between the second portion 40b and the third portion 40c; the p⁺⁺-type connecting region 57 has a function of mitigating electric field near the third portion 40c. In the present embodiment, the step 45 is not formed in the edge termination region 33 or at a position adjacent to the edge termination region 33 and thus, p-type regions (the p⁺-type outer peripheral region 51, the p-type outer peripheral base region 52, and the p⁺⁺-type outer peripheral region 53) exposed at the third portion 40c of the front surface of the semiconductor substrate 40 suffice to all be connected and the p⁺⁺-type connecting region 57 may be omitted (refer to FIG. 2).

An interlayer insulating film 9 is provided in nearly an entire area of the front surface of the semiconductor substrate 40 and covers all the gate electrodes 8. In the active-region operating portion 31a, contact holes exposing the n⁺-type source regions 4 and the p⁺⁺-type contact regions 5 are provided in the interlayer insulating film 9. The ohmic electrodes 17 are in ohmic contact with the semiconductor substrate 40 in the contact holes. The ohmic electrodes 17 are constituted by, for example, a nickel silicide (NixSiy, where, x, y are positive numbers) film formed with the semiconductor substrate 40. A barrier metal 18 covers substantially the entire surfaces of the interlayer insulating film 9 and the ohmic electrodes 17 in the active-region operating portion 31a. The barrier metal 18 has a function of preventing atomic diffusion and interaction between the source electrode 11 and the semiconductor substrate 40.

The source electrode 11 is provided in substantially an entire area of the front surface (the first portion 40a) of the semiconductor substrate 40 in the active-region operating portion 31a and is electrically connected to the n⁺-type source regions 4 and the p⁺⁺-type contact regions 5 via the barrier metal 18 and the ohmic electrodes 17. The source electrode 11 is formed by an aluminum (Al) alloy film 11a (or an Al film), a plating film 11b, and a soldering layer 11c sequentially stacked in the order stated. The Al alloy film 11a is provided at the surface of the barrier metal 18. The plating film 11b is provided at the surface of the Al alloy film 11a. The plating film 11b has a function of enhancing solder wettability during formation of the soldering layer 11c. A terminal pin 19 (or bonding wire: not depicted) is soldered to the plating film 11b, via the soldering layer 11c.

The plating film 11b and the soldering layer 11c are provided in an opening of a passivation film 20. The terminal pin 19 is a round bar-shape (cylindrical) wiring member soldered to the plating film 11b in an upright state substantially orthogonal to the front surface of the semiconductor substrate 40. The passivation film 20 covers portions of the surface of the Al alloy film 11a, excluding a portion covered by the plating film 11b. The passivation film 20 covers an outer peripheral end of the plating film 11b. A portion of the plating film 11b exposed in the opening of the passivation film 20 functions as a source pad. In an entire area of the back surface (back surface of the n⁺-type starting substrate 41) of the semiconductor substrate 40, a drain electrode (second electrode) 24 is provided. The drain electrode 24 is in ohmic contact with the back surface of the semiconductor substrate 40 and is electrically connected to the n⁺-type drain region 1 (the n⁺-type starting substrate 41).

The second portion 40b of the front surface of the semiconductor substrate 40 is covered by an insulating layer in which the field oxide film 71 and the interlayer insulating film 9 are sequentially stacked in the order stated. The field oxide film 71 extends toward the active-region operating portion 31a, between the front surface of the semiconductor substrate 40 and the interlayer insulating film 9; the field oxide film 71 covers the third portion 40c of the front surface of the semiconductor substrate 40 and terminates on the first portion 40a. The gate polysilicon wiring layer 74, 76 and the gate resistor 14 (in FIGS. 2 to 5, not depicted) are provided between the interlayer insulating film 9 and the field oxide film 71 in the active-region non-operating portion 31b. The gate polysilicon wiring layer 72 is provided between the interlayer insulating film 9 and the field oxide film 71 in the boundary region 32. The gate polysilicon wiring layers 72, 74, 76 are exposed in different contact holes of the interlayer insulating film 9, respectively.

The gate pad 12, the gate runner 13, and the gate ring 15, through the respective contact holes thereof, are electrically connected to the gate polysilicon wiring layers 74, 76, 72 via the barrier metals 75, 77, 73. The gate polysilicon wiring layer 74 directly beneath the gate pad 12 is connected to one end of the gate resistor 14. The gate polysilicon wiring layer 76 directly beneath the gate runner 13 is connected to the other end of the gate resistor 14 and is electrically connected to the gate pad 12 via the gate resistor 14. The gate resistor 14 is formed by ion implantation of an n-type dopant in the polysilicon or the like. The gate electrodes 8 of all the cells of the MOSFET are connected to any one of or both the gate polysilicon wiring layers 76, 72 directly beneath the gate runner 13 and the gate ring 15. Each of the barrier metals 73, 75, 77 has a function of preventing atomic diffusion and interaction between layers facing and sandwiching the barrier metals 73, 75, 77. The barrier metal 73, 75, 77, for example, are formed concurrently with the barrier metal 18. In an instance in which the gate resistor 14 is not provided internally, the gate pad 12 and the gate polysilicon wiring layer 74 directly beneath the gate pad 12 may be in contact with each other.

In the interlayer insulating film 9 and the field oxide film 71, a contact hole exposing the p⁺⁺-type outer peripheral contact region 54 is provided closer to the chip end than is the gate ring 15. In the contact hole, the ohmic electrode 55 is in ohmic contact with the semiconductor substrate 40. The source ring 16 is electrically connected to the p⁺⁺-type outer peripheral contact regions 54, via a barrier metal 56 and the ohmic electrode 55. The ohmic electrode 55 and the barrier metal 56, for example, are formed concurrently with the ohmic electrodes 17 and the barrier metal 18, respectively. The gate pad 12, the gate runner 13, the gate ring 15, and the source ring 16, for example, are formed concurrently with the Al alloy film 11a. An entire area of the surfaces of the gate pad 12, the gate runner 13, the gate resistor 14, the gate ring 15, the source ring 16, and the gate polysilicon wiring layers 72, 74, 76 faces the p⁺-type outer peripheral region 51 in the depth direction Z.

Between the second portion 40b of the front surface of the semiconductor substrate 40 and the n--type drift region 2, multiple p-type regions (hereinafter, FLRs) 61 and multiple p--type regions (hereinafter, FLRs) 62 configuring the voltage withstanding structure 60, and the n⁺-type channel stopper region 63 are each selectively provided in contact with the n⁻-type drift region 2. Here, while an example in which the voltage withstanding structure 60 is a field limiting ring (FLR) structure is described, the voltage withstanding structure 60 may be a junction termination extension (JTE) structure.

The FLRs 61, 62, for example, configure a spatially modulated structure. The spatially modulated structure is a voltage withstanding structure in which a p-type dopant concentration per unit volume decreases stepwise in a direction to the chip end. The multiple FLRs 61 surround the periphery of the boundary region 32 in concentric shapes apart from one another. The closer a FLR 61 of the FLRs 61 is disposed to the chip end, the narrower is a width (width in a direction from the chip center to the chip end) of said FLR 61 and the narrower is an interval between said FLR 61 and an adjacent one of the FLRs 61 adjacent thereto and closer to the chip center than is said FLR 61. Of the FLRs 62, a nearest one to the chip center borders peripheries of all the FLRs 61 and is disposed between all the FLRs 61 that are adjacent to one another. Of the FLRs 61, a nearest one to the chip center and the nearest one to the chip center of the FLRs 62 are in contact with the p-type outer peripheral region 50.

The multiple FLRs 62 surround the periphery of the boundary region 32 in concentric shapes apart from one another. The closer a FLR 62 of the FLRs 62 is disposed to the chip end, the narrower is a width (width in a direction from chip center to the chip end) thereof and the narrower is an interval between said FLR 62 and an adjacent one of the FLRs 62 adjacent thereto and closer to the chip center than is said FLR 62. The FLRs 62, excluding the one closest to the chip center of the FLRs 62, are disposed closer to the chip end than are the FLRs 61. The n⁻-type drift region 2 extends between the FLRs 62 that are adjacent to one another; the n⁻-type drift region 2 reaches the second portion 40b of the front surface of the semiconductor substrate 40. The n⁻-type drift region 2 borders the peripheries of all the FLRs 62 and is disposed between the FLRs 62 that are adjacent to one another.

The n⁺-type channel stopper region 63 is provided apart from the voltage withstanding structure 60 and closer to the chip end than is the voltage withstanding structure 60. The n⁺-type channel stopper region 63 is exposed at the chip end (side surface of the semiconductor substrate 40). Instead of the n⁺-type channel stopper region 63, a p⁺-type channel stopper region may be provided. The FLRs 61, 62 and the n⁺-type channel stopper region 63 are diffused regions formed by ion implantation in surface regions of the n⁻-type epitaxial layer 42. The passivation film 20 covers substantially an entire area of an uppermost surface (i.e., the surface of the interlayer insulating film 9) of the front surface of the semiconductor substrate 40 and is a surface protecting film for protecting the front surface of the semiconductor substrate 40.

Operation of the semiconductor device 10 according to the embodiment is described. When voltage that is positive with respect to the source electrode 11 is applied to the drain electrode 24 and voltage at least equal to a gate threshold voltage is applied to the gate electrodes 8, channels (n-type inversion layers) are formed along the sidewalls of the trenches 6, in regions of the p-type base region 3 between the n-type current spreading region 23 and the n⁺-type source regions 4. As a result, drift current (main current) flows from the n⁺-type drain region 1, through the n⁻-type drift region 2, the n-type current spreading region 23, and the channels, to the n⁺-type source regions 4 and the MOSFET turns on.

On the other hand, when voltage that is positive with respect to the source electrode 11 is applied to the drain electrode 24 and a voltage that is less than the gate threshold voltage is applied to the gate electrodes 8, pn junctions (main junctions) between the p-type base region 3, the p⁺-type regions 21, 22, the n-type current spreading region 23, and the n⁻-type drift region 2 are reverse biased, whereby the MOSFET maintains the off-state. From the pn junctions, a depletion layer spreads in a vertical direction (direction toward the source electrode 11 and direction toward the drain electrode 24) in the active-region operating portion 31a; and from the active-region operating portion 31a, a depletion layer spreads in a lateral direction to the active-region non-operating portion 31b and the boundary region 32. In the active-region operating portion 31a, the n⁻-type drift region 2 depletes, whereby a predetermined breakdown voltage of the active-region operating portion 31a is ensured.

Further, in the active-region non-operating portion 31b and the boundary region 32, pn junctions between the p-type outer peripheral region 50 and the n⁻-type drift region 2 are reverse biased, whereby in the n⁻-type drift region 2, a depletion layer spreads in a direction to the edge termination region 33, from the active-region non-operating portion 31b and the boundary region 32. Furthermore, in the edge termination region 33, pn junctions between the FLRs 61, 62 and the n⁻-type drift region 2 are reverse biased, whereby in the edge termination region 33, a depletion layer spreads in a lateral direction in the n⁻-type drift region 2. A predetermined breakdown voltage of the edge termination region 33 based on a critical dielectric field strength of the semiconductor material is ensured to an extent that the depletion layer spreads toward the chip end, in the n⁻-type drift region 2 in the edge termination region 33.

During a period while the MOSFET transitions from on to off, parasitic pn junction diodes (body diodes) formed by pn junctions between the p-type base region 3, the p⁺-type regions 21, 22, the p-type outer peripheral region 50, the n-type current spreading region 23, and the n⁻-type drift region 2 conduct in a forward direction, and minority carriers (holes and electrons) are injected into and accumulate in the n⁻-type drift region 2. When the MOSFET turns off from this state (reverse recovery of the body diodes), holes in the n⁻-type drift region 2 are discharged to the source electrode 11 or the source ring 16 and the MOSFET turns off. At this time, in the edge termination region 33, holes in the n⁻-type drift region 2 easily flow into the p-type outer peripheral region 50, pass through the p-type outer peripheral region 50, and are discharged to the source ring 16.

The semiconductor substrate 40 has a stacked structure in which, in an entire area excluding the active-region operating portion 31a, portions where the crystallinity is superior to the crystallinity of the n⁻-type epitaxial layer 42 are completely removed. The p-type outer peripheral region 50 and the FLRs 61, 62 are diffused regions formed in the n⁻-type epitaxial layer 42 and the lifetime of the minority carriers therein is substantially the same as the lifetime of the minority carriers of the n⁻-type drift region. Thus, among the active-region non-operating portion 31b, the boundary region 32, and the edge termination region 33, there is nearly no variation of the period until reverse recovery current (hole current) of the body diodes is blocked. As a result, in the active-region non-operating portion 31b, the boundary region 32, and the edge termination region 33, local concentration of hole current may be suppressed.

As described above, according to the embodiment, in an entire area excluding the active-region operating portion, portions where the crystallinity is superior to the crystallinity of the n⁻-type drift region are completely removed. In other words, in the active-region non-operating portion, the boundary region, and the edge termination region, portions where the lifetime of the minority carriers is longer than the lifetime of the minority carriers in the n⁻-type drift region are completely removed, whereby the lifetime of the minority carriers becomes substantially uniform. Thus, the lifetime of the minority carriers in the p-type outer peripheral region provided in the entire area between the front surface of the semiconductor substrate and the n⁻-type drift region in the active-region non-operating portion and the boundary region and the lifetime of the minority carriers of p-type regions (FLRs) that form the voltage withstanding structure and are selectively provided between the front surface of the semiconductor substrate and the n⁻-type drift region in the edge termination region, become substantially the same.

As a result, when the MOSFET turns off (during reverse recovery of body diodes), the period until reverse recovery current (hole current) of the body diodes is blocked may be made substantially uniform in the active-region non-operating portion, the boundary region, and the edge termination region. Thus, in the active-region non-operating portion, the boundary region, and the edge termination region, local concentration of hole current may be suppressed and reverse recovery characteristics of the body diodes may be improved, whereby breakdown tolerance of the MOSFET during switching and particularly capability against steep dV/dt may be increased. Further, for example, even when the temperature of the semiconductor substrate is low such as about −40 degrees C. or about −55 degrees C., as compared to the reference structure (refer to FIGS. 6 to 9), reverse recovery current of the body diodes easily flows in the p-type outer peripheral region, and breakdown tolerance when the junction temperature is low is enhanced.

In the foregoing, the present invention is not limited to the embodiments described and various modifications within a range not departing from the spirit of the invention are possible. For example, in the embodiments described, instead of the trench gate structure having gate electrodes that extend in the depth direction from the front surface of the semiconductor substrate, plate-like gate electrodes extending along the front surface of the semiconductor substrate may be provided as a planar gate structure. In an instance in which the present invention is applied to a planar gate structure, in an entire area excluding the active-region operating portion, portions where the crystallinity is superior to the crystallinity of the n⁻-type drift region are completely removed, whereby a distance from a step formed at the front surface of the semiconductor substrate to an end of the gate electrode closest to the step suffices to be about 5 μm or less. Further, the gate runner may be provided in the boundary region. In the active-region non-operating portion and/or the boundary region, other circuit structures may be further provided in addition to the main semiconductor device.

Further, application of the present invention is not limited to a MOSFET, and the present invention may be applied to an insulated gate bipolar transistor (IGBT), a bipolar junction transistor (BJT), vertical semiconductor devices having a pn junction such as a p-intrinsic-n (pin) diode, etc. The present invention may be applied to cases in which silicon (Si) or gallium nitride (GaN) is used as a semiconductor material. Further, in the embodiments described, while the first conductivity type is assumed to be an n-type and the second conductivity type is assumed to be a p-type, the present invention is similarly implemented when the first conductivity type is a p-type and the second conductivity type is an n-type.

According to the present invention, during reverse recovery of a diode formed by a pn junction between the second semiconductor region and the first semiconductor region, the period until reverse recovery current (hole current) is blocked may be made substantially uniform in an entire area excluding the active region. Thus, in the entire area excluding the active region, local concentration of hole current may be suppressed.

The semiconductor device according to the present invention achieves an effect in that breakdown tolerance may be enhanced.

As described, the semiconductor device according to the present invention is useful for power semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having a first main surface and a second main surface opposite to each other;
an active region provided in the semiconductor substrate;
a termination region surrounding a periphery of the active region;
a boundary region between the active region and the termination region;
a first semiconductor region of a first conductivity type, provided in the semiconductor substrate, spanning the active region to the termination region;
a second semiconductor region of a second conductivity type, provided between the first semiconductor region and the first main surface of the semiconductor substrate;
a device structure provided in the active region, the device structure having a pn junction between the second semiconductor region and the first semiconductor region;
a second-conductivity-type outer peripheral region provided in the boundary region, between the first main surface and the first semiconductor region;
a first electrode provided at the first main surface, and electrically connected to the device structure and the second-conductivity-type outer peripheral region; and
a second electrode provided at the second main surface of the semiconductor substrate, wherein
the semiconductor substrate has a stacked structure including:
a first epitaxial layer of the first conductivity type having the second-conductivity-type outer peripheral region therein at a first main surface side thereof, and a remaining portion of the first epitaxial layer, excluding the second-conductivity-type outer peripheral region, constitutes the first semiconductor region, and
a second epitaxial layer provided on the first epitaxial layer, the second epitaxial layer is provided only in the active region and has the device structure, and
the first main surface in the active region is formed by the second epitaxial layer, and the first main surface outside the active region is formed by the first epitaxial layer.

2. The semiconductor device according to claim 1, wherein the active region has:
an active-region operating portion in which the device structure is provided, and
an active-region non-operating portion free of the device structure, the second-conductivity-type outer peripheral region is further provided in
the active-region non-operating portion, between the first main surface and the first semiconductor region,
the second epitaxial layer is provided in the active-region operating portion but not in the active-region non-operating portion, and
the second epitaxial layer forms only the first main surface in the active-region operating portion, and the first main surface outside the active-region non-operating portion is formed by the first epitaxial layer.

3. The semiconductor device according to claim 2, wherein
the device structure is an insulated gate structure having a metal-oxide-semiconductor three-layer structure, and
the semiconductor device further comprises, in the active-region non-operating portion, a gate pad provided at the first main surface via an insulating layer, the gate pad facing the second-conductivity-type outer peripheral region in a depth direction, the gate pad being electrically connected to a gate electrode configuring the insulated gate structure.

4. The semiconductor device according to claim 2, wherein
the device structure is an insulated gate structure having a metal-oxide-semiconductor three-layer structure, and
the semiconductor device further comprises, in the active-region non-operating portion, a gate wiring layer provided at the first main surface via an insulating layer, the gate wiring layer facing the second-conductivity-type outer peripheral region in a depth direction, the gate wiring layer being electrically connected to a gate electrode configuring the insulated gate structure.

5. The semiconductor device according to claim 1, wherein
the device structure is an insulated gate structure having a metal-oxide-semiconductor three-layer structure, and
the semiconductor device further comprises a gate wiring layer provided in the boundary region, at the first main surface via an insulating layer, the gate wiring layer facing the second-conductivity-type outer peripheral region in depth direction, the gate wiring layer being electrically connected to a gate electrode configuring the insulated gate structure.

6. A semiconductor device, comprising:
a semiconductor substrate having a first main surface and a second main surface opposite to each other;
an active region provided in the semiconductor substrate;
a termination region surrounding a periphery of the active region;
a boundary region between the active region and the termination region;
a first semiconductor region of a first conductivity type, provided in the semiconductor substrate, spanning the active region to the termination region;
a second semiconductor region of a second conductivity type, provided between the first main surface of the semiconductor substrate and the first semiconductor region;
a device structure provided in the active region, the device structure having a pn junction between the second semiconductor region and the first semiconductor region;
a second-conductivity-type outer peripheral region provided in the boundary region, between the first main surface and the first semiconductor region;
a first electrode provided at the first main surface, and electrically connected to the device structure and the second-conductivity-type outer peripheral region; and
a second electrode provided at the second main surface of the semiconductor substrate, wherein
the semiconductor substrate has a structure in which a region outside the active region is free of a minority carrier lifetime that is longer than a minority carrier lifetime of the first semiconductor region in the active region.

7. The semiconductor device according to claim 6, wherein
the active region has:
an active-region operating portion in which the device structure is provided, and
an active-region non-operating portion free of the device structure,
the second-conductivity-type outer peripheral region is further provided in the active-region non-operating portion, between the first main surface and the first semiconductor region, and
the semiconductor substrate has a structure in which a region outside the active-region operating portion is free of the minority carrier lifetime that is longer than the minority carrier lifetime of the first semiconductor region in the active-region operating portion.

8. The semiconductor device according to claim 7, wherein
the device structure is an insulated gate structure having a metal-oxide-semiconductor three-layer structure, and
the semiconductor device further comprises, in the active-region non-operating portion, a gate pad provided at the first main surface via an insulating layer, the gate pad facing the second-conductivity-type outer peripheral region in a depth direction, the gate pad being electrically connected to a gate electrode configuring the insulated gate structure.

9. The semiconductor device according to claim 7, wherein
the device structure is an insulated gate structure having a metal-oxide-semiconductor three-layer structure, and
the semiconductor device further comprises, in the active-region non-operating portion, a gate wiring layer provided at the first main surface via an insulating layer, the gate wiring layer facing the second-conductivity-type outer peripheral region in a depth direction, the gate wiring layer being electrically connected to a gate electrode configuring the insulated gate structure.

10. The semiconductor device according to claim 6, wherein
the device structure is an insulated gate structure having a metal-oxide-semiconductor three-layer structure, and
the semiconductor device further comprises a gate wiring layer provided in the boundary region, at the first main surface via an insulating layer, the gate wiring layer facing the second-conductivity-type outer peripheral region in depth direction, the gate wiring layer being electrically connected to a gate electrode configuring the insulated gate structure.

11. A semiconductor device, comprising:
a semiconductor substrate having a first main surface and a second main surface opposite to each other;
an active region provided in the semiconductor substrate;
a termination region surrounding a periphery of the active region;
a boundary region between the active region and the termination region;
a first semiconductor region of a first conductivity type, provided in the semiconductor substrate, spanning the active region to the termination region;
a second semiconductor region of a second conductivity type, provided between the first main surface of the semiconductor substrate and the first semiconductor region;
a device structure provided in the active region, the device structure having a pn junction between the second semiconductor region and the first semiconductor region;
a second-conductivity-type outer peripheral region provided in the boundary region, between the first main surface and the first semiconductor region;
a first electrode provided at the first main surface, and electrically connected to the device structure and the second-conductivity-type outer peripheral region; and
a second electrode provided at the second main surface of the semiconductor substrate, wherein
the semiconductor substrate has a structure including an epitaxial layer in which a region outside the active region is free of a crystallinity that is relatively superior to a crystallinity of the active region.

12. The semiconductor device according to claim 11, wherein
the active region has:
an active-region operating portion in which the device structure is provided, and
an active-region non-operating portion free of the device structure,
the second-conductivity-type outer peripheral region is provided in the active-region non-operating portion, between the first main surface and the first semiconductor region, and
in the epitaxial layer, in a region outside the active-region operating portion is free of a crystallinity that is relatively superior to a crystallinity of the active-region operating portion.

13. The semiconductor device according to claim 12, wherein
the device structure is an insulated gate structure having a metal-oxide-semiconductor three-layer structure, and
the semiconductor device further comprises, in the active-region non-operating portion, a gate pad provided at the first main surface via an insulating layer, the gate pad facing the second-conductivity-type outer peripheral region in a depth direction, the gate pad being electrically connected to a gate electrode configuring the insulated gate structure.

14. The semiconductor device according to claim 12, wherein
the device structure is an insulated gate structure having a metal-oxide-semiconductor three-layer structure, and
the semiconductor device further comprises, in the active-region non-operating portion, a gate wiring layer provided at the first main surface via an insulating layer, the gate wiring layer facing the second-conductivity-type outer peripheral region in a depth direction, the gate wiring layer being electrically connected to a gate electrode configuring the insulated gate structure.

15. The semiconductor device according to claim 11, wherein
the device structure is an insulated gate structure having a metal-oxide-semiconductor three-layer structure, and
the semiconductor device further comprises a gate wiring layer provided in the boundary region, at the first main surface via an insulating layer, the gate wiring layer facing the second-conductivity-type outer peripheral region in depth direction, the gate wiring layer being electrically connected to a gate electrode configuring the insulated gate structure.
